(19) United States
(12) Patent Application Publication
(10) Pub. No.: US 2026/0025941 A1
(43) Pub. Date: Jan. 22, 2026

(54) LED display board

(71) Applicant: Won Sun HWANG, Seoul (KR)

(72) Inventor: Won Sun HWANG, Seoul (KR)

(21) Appl. No.: 19/267,663

(22) Filed: Jul. 14, 2025

(30) Foreign Application Priority Data
Jul. 16, 2024 (KR) 10-2024-0093699
Mar. 13, 2025 (KR) 10-2025-0032555

(51) Int. Cl. H05K 7/18

(52) U.S. Cl. CPC H05K 7/18

(57) ABSTRACT

Proposed is an LED display board including a plurality of edge beams that provides a square installation frame, a plurality of vertical beams and horizontal beams installed on the inside of the edge beams, and a plurality of LED modules installed at the front of the installation frame, wherein the LED modules are directly mounted on the installation frame.

### CROSS REFERENCE TO RELATED APPLICATION

The present application claims priority to Korean Patent Application Nos. 10-2024-0093699, filed Jul. 16, 2024, and 10-2025-0032555, filed Mar. 13, 2025, the entire contents of which are incorporated herein for all purposes by this reference.

### BACKGROUND

### Technical Field

The present disclosure relates to an LED display board with a removable LED module attached.

### Description of the Related Art

As shown in FIGS. 1 to 3, an LED display board is installed with multiple cabinets CB, on which multiple LED modules LMs are mounted, on a wall frame in which a vertical frame VF and an edge frame ED are connected using bolts to form a square. As shown, the wall frame is formed into a square shape by fixing end fixing plates or corner fixing plates of an approximately pentagonal or triangular shape to the vertical frame VF and the edge frame ED by bolted connections.

The cabinet CB is installed vertically on the wall frame by being bolted to a bolt-fastening bracket BK provided on the vertical frame VF as shown in FIGS. 1 to 3. In addition, the LED module LM is installed on the wall frame via the cabinet CB.

However, in the case of the aforementioned cabinet CB, in order to replace one LED module LM, all LED modules LM installed in the cabinet CB need to be disassembled as shown in FIG. 4.

Korean Patent No. 10-2010709 (Applicant: DRSIS Co., Ltd.) relates to an LED display board that can solve the above shortcomings. As shown in the drawing, multiple cabinets 2 equipped with LED modules 3 are bolted to a vertical frame VF by means of a bolt-fastening bracket BK of a wall frame, and a cabinet fastening part 10 is provided so that the cabinets 2 may be connected in a one-touch manner.

The problem is that because the aforementioned cabinets are manufactured by die casting, a post-processing process to remove burrs is essential, and when installed on the vertical frame, installation errors (horizontal and vertical misalignment) occur due to processing dispersion during molding, which need to be corrected one by one. When attaching the LED modules, installation errors also occur due to processing dispersion. If these errors are not accurately corrected, accumulated errors occur, and the screen is ultimately installed in a distorted state.

Moreover, since installation errors occur even when installing the vertical frame on the wall, the cabinets should be installed considering such installation errors. Therefore, the installation work of the conventional technology is very difficult, and because the cabinet should be bolted using the bolt-fastening bracket, not only is excessive bolt usage required, but the installation time is also excessively taken.

In addition, since multiple cabinets are installed in the wall frame in the conventional technology, stress due to the load of the cabinets may be applied to the wall, and accordingly, installation is only possible in a wall that can bear the load of the cabinets, which makes installation very limited.

### Document of Related Art

(Patent Document 1) Korean Patent No. 10-2010709 (Applicant: DRSIS Co., Ltd.)

### SUMMARY

Accordingly, the present disclosure has been made keeping in mind the above problems occurring in the related art, and the present disclosure is intended to provide an LED display board that can prevent the occurrence of a variety of errors as described above and, in particular, can omit the conventional cabinet described above.

In order to achieve the above objective, according to an aspect of the present disclosure, there is provided an LED display board including: a plurality of edge beams connected in a square ring shape to provide a square installation frame; a plurality of vertical beams installed spaced apart from each other on an inside of the edge beams; a plurality of horizontal beams installed spaced apart from each other along a length direction of the vertical beams to form a grid together with the vertical beams; and a plurality of LED modules detachably installed at the front of the horizontal beams along a length direction of the horizontal beams, and each having a magnetic body or magnet on a rear side thereof facing the horizontal beams or the edge beams so as to be detachably fixed to the horizontal beams or the edge beams using a magnetic force.

The plurality of horizontal beams may be provided with another magnetic body or magnet that provides an attractive force to the magnetic body or the magnet of each of the LED modules.

The each of the edge beams may be provided with a head hole, into which a head of a bolt that is fastened to an end of each of the vertical beams or horizontal beams is inserted, and a shaft hole, through which a shaft of the bolt having threads formed passes, separated from each other, and may be composed of a tube with a hollow formed therein, wherein the head hole and the shaft hole may face each other with the hollow as the center.

In the present disclosure, at least one of each of the vertical beams or each of the horizontal beams may further include a notch into which a portion of a counterpart to be joined in the grid is inserted and hung.

The each of the vertical beams and horizontal beams may be prevented from being detached by having the portion thereof supported on an inside of the notch or caught in the notch as the portion thereof is inserted into the notch.

The each of the horizontal beams may have a bolt hole formed at an end thereof to which a bolt is fastened that horizontally penetrates each of the edge beams, may be composed of a tube with a hollow formed therein.

The each of the horizontal beams may further include an uneven protrusion on which another magnetic body or magnet is installed.

The present disclosure may further include: a catch pin protruding on the rear side of the each of the LED modules provided with the magnetic body or magnet; and a groove-shaped holder formed integrally with each of the horizontal beams and edge beams and into which the catch pin is inserted and caught.

According to the present disclosure as described above, since an LED module is directly attached to the components of the installation frame consisting of a vertical beam and an edge beam, a horizontal beam and an edge beam, or a vertical beam, a horizontal beam, and an edge beam, a conventional cabinet can be omitted, and accordingly, post-processing caused by the cabinet, and occurrence of a variety of errors and accumulated errors resulting therefrom can be minimized.

In particular, since the cabinet is omitted, the overall dead weight is significantly reduced, which reduces the stress on a wall. Accordingly, the restriction criteria for the wall on which the present disclosure is to be installed can be expanded. Furthermore, since the edge beam, vertical beam, and horizontal beam are hollow aluminum profile beams, weight reduction is possible and processing such as cutting or slicing can be easily performed.

### BRIEF DESCRIPTION OF THE DRAWINGS

The above and other objectives, features, and other advantages of the present disclosure will be more clearly understood from the following detailed description when taken in conjunction with the accompanying drawings, in which:

FIGS. 1 to 3 are views showing the wall frame of a typical LED display board;

FIG. 4 is a perspective view of an LED display board of conventional technology;

FIG. 5 is a view schematically showing the entire wall frame according to an embodiment of the present disclosure;

FIG. 6 is an enlarged view of a part of FIG. 5;

FIGS. 7A and 7B are enlarged views of the cross-sectional view and side cross-sectional view shown in FIG. 6;

FIG. 8 is an enlarged view of the cross-sectional view shown in FIG. 7A;

FIG. 9 is an enlarged view of the side cross-sectional view shown in FIG. 7B;

FIGS. 10A and 10B are a side view and a plan view of the edge beam shown in FIG. 5;

FIG. 11 shows a plan view, front view, and side view of the anchor bracket illustrated in FIG. 9;

FIG. 12 is a side view showing the state of use of the anchor bracket illustrated in FIG. 11;

FIGS. 13A to 13C show a front view and a side view of the horizontal beam illustrated in FIG. 5;

FIGS. 14A to 14C show various usage states of the horizontal beam illustrated in FIGS. 13A to 13C;

FIGS. 15A and 15B are a front view and a rear view showing another embodiment of the horizontal beam illustrated in FIG. 5;

FIGS. 16A and 16B are plan views of the horizontal beam illustrated in FIGS. 15A and 15B;

FIGS. 17A to 17C show various usage states of the horizontal beam illustrated in FIGS. 15A and 15B;

FIG. 18 is an exploded perspective view of the vertical beam and horizontal beam illustrated in FIG. 5;

FIG. 19 is a front view of the horizontal adjuster illustrated in FIG. 5;

FIG. 20 is a side view of the horizontal adjuster illustrated in FIG. 19;

FIG. 21 is an exploded perspective view schematically showing the configuration of the horizontal adjuster illustrated in FIG. 19;

FIGS. 22A and 22B are side views showing the state of use of the horizontal adjuster illustrated in FIG. 19; and

FIG. 23 shows a plan view, side view, and front view of the board housing illustrated in FIG. 5.

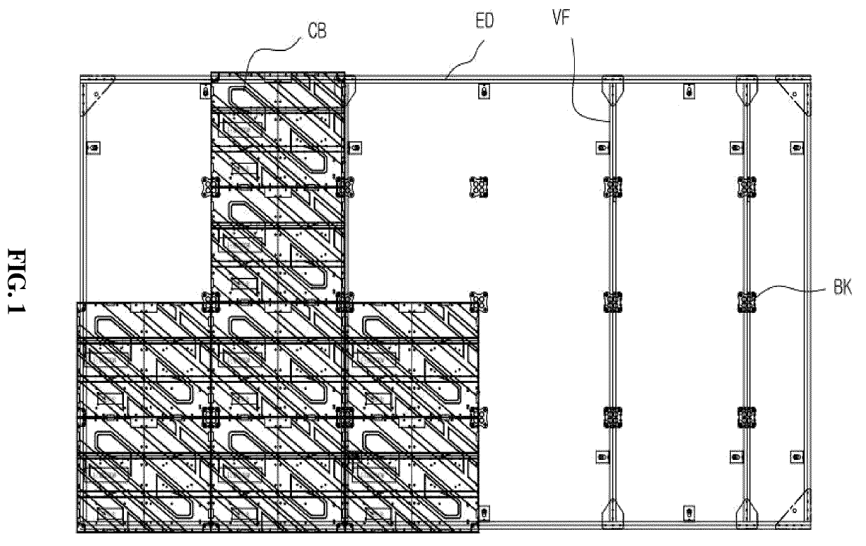

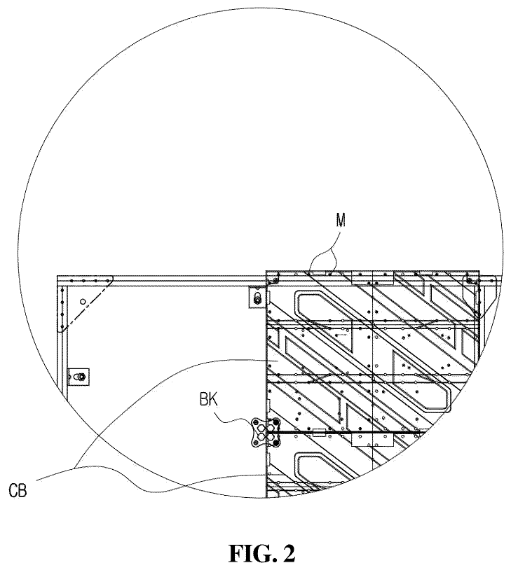

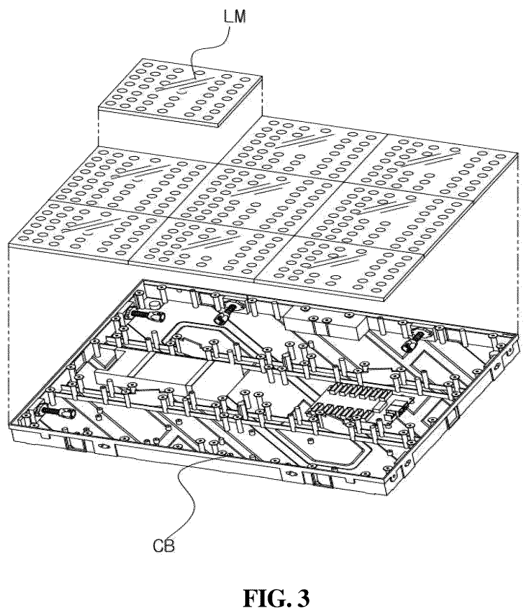

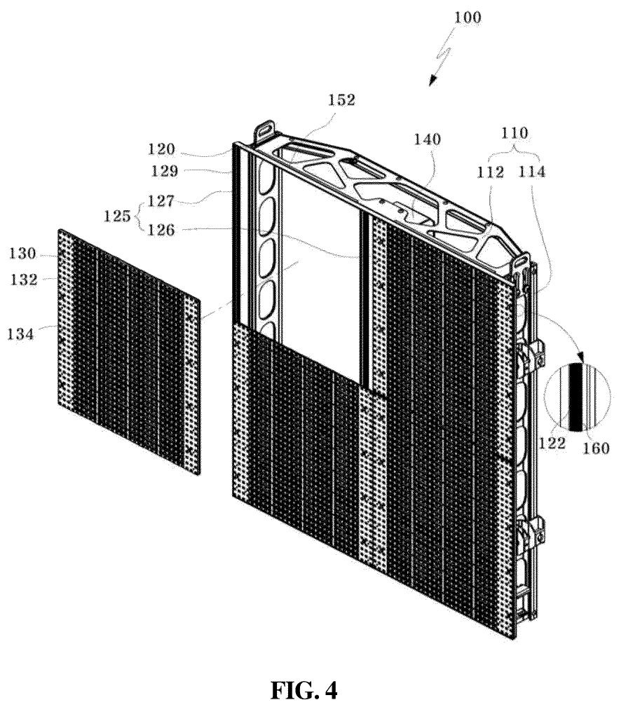

### DETAILED DESCRIPTION

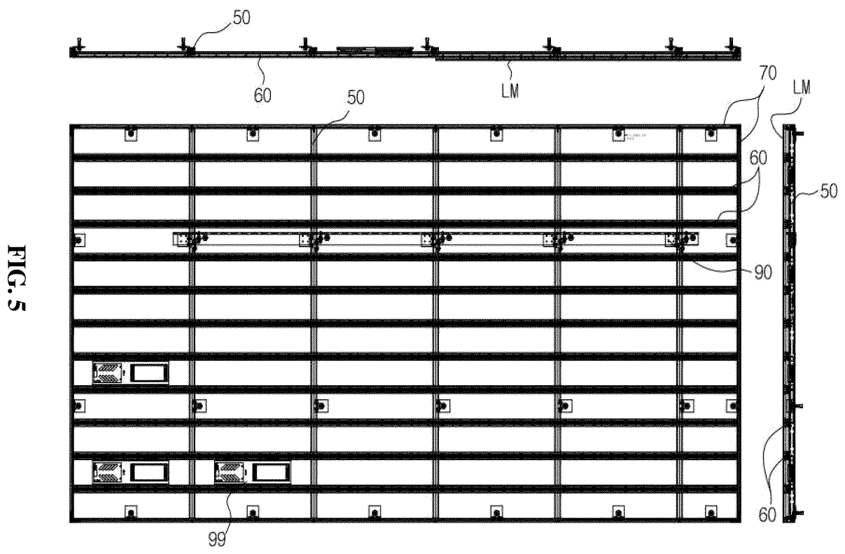

As shown in FIG. 5, an LED display board according to an embodiment of the present disclosure includes: a square installation frame consisting of a plurality of edge beams 70, and an inner beam consisting of at least one of a plurality of vertical beams 50 installed vertically and a plurality of horizontal beams 60 installed horizontally; and a plurality of LED modules LM installed on at least one of the plurality of horizontal beams 60, the plurality of vertical beams 50, and the plurality of edge beams 70. The edge beams 70 are connected in a square ring as shown to provide a square frame. The edge beams 70 are installed with at least one of the plurality of vertical beams 50 or horizontal beams 60 spaced apart vertically or horizontally. In the case that the horizontal beams 60 are installed together with the vertical beams 50, the horizontal beams 60 are installed horizontally while being spaced apart from each other along the length direction of the vertical beams 50 as shown. Thus, the horizontal beams 60 intersect with the vertical beams 50 and form a grid together with the vertical beams 50. The LED modules LM may be installed at the front of the plurality of vertical beams 50, horizontal beams 60, and edge beams 70, but it is preferable that the LED modules LM are removably installed at the front of the horizontal beams 60 along the length direction of the horizontal beams 60, as shown.

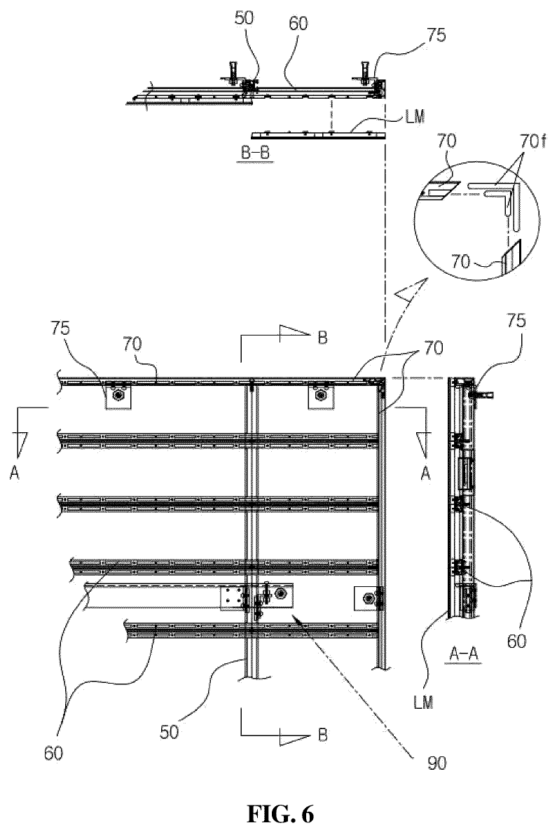

As shown in FIGS. 6 to 10B, the ends of the edge beams 70 cut in an inclined state are connected in a close state. Thus, the edge beams 70 provide a square frame shaped in a square ring as shown.

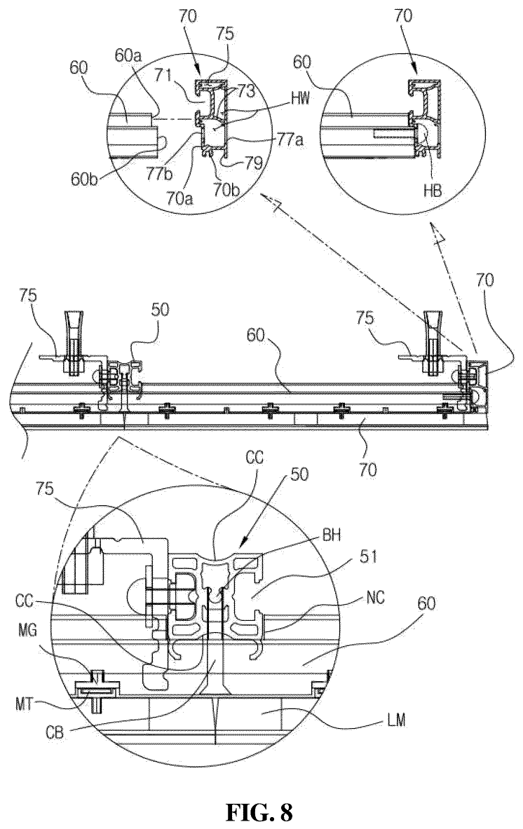

The edge beam 70 is composed of a tube with a hollow HW formed therein as shown in FIG. 8. Since the edge beam 70 is manufactured in the shape of a square tube as shown by extrusion, it is preferable that the edge beam 70 be composed of a profile having the hollow HW along the length direction. In particular, it is preferable that the edge beam 70 is composed of an aluminum profile for weight reduction. The edge beam 70 has at least one rib 73 as shown to have a plurality of hollows HW. The rigidity of the edge beam 70 weakened by the hollows HW is reinforced by the rib 73. Thus, the edge beam 70 is able to maintain rigidity even if the edge beam 70 is lightweight.

As shown in the enlarged view in FIG. 6, a right-angled bent plate 70f is inserted into the portion of the edge beam 70 forming the corner and fixed. The bent plate 70f is fixed to the upper edge beam 70 and the side edge beam 70 forming the corner using bolts after the opposite ends of the bent plate 70f are inserted into the hollows HW formed in the upper edge beam 70 and the side edge beam 70 respectively. Thus, the upper edge beam 70 and the side edge beam 70 may be maintained in an orthogonal state due to the bent plate 70f inserted and fixed thereinside, thereby providing a right-angled corner to the square frame. The edge beams 70 may also be fixed at right angles at the corners by means of a corner fixing plate applied in the conventional technology.

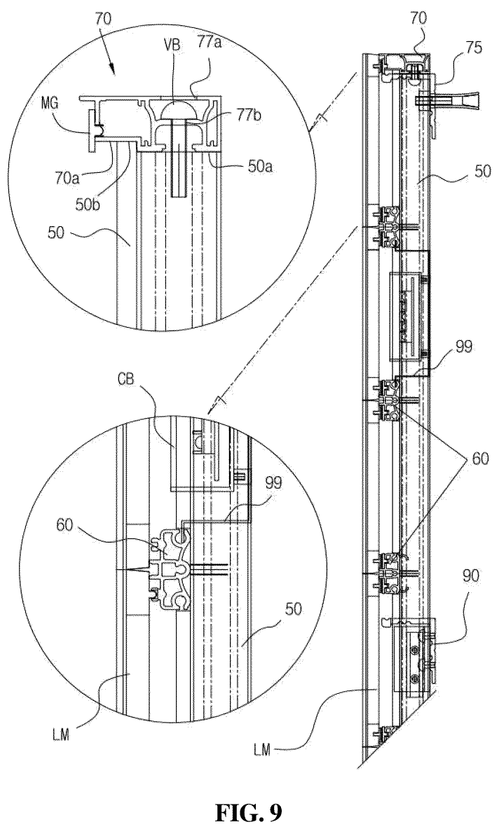

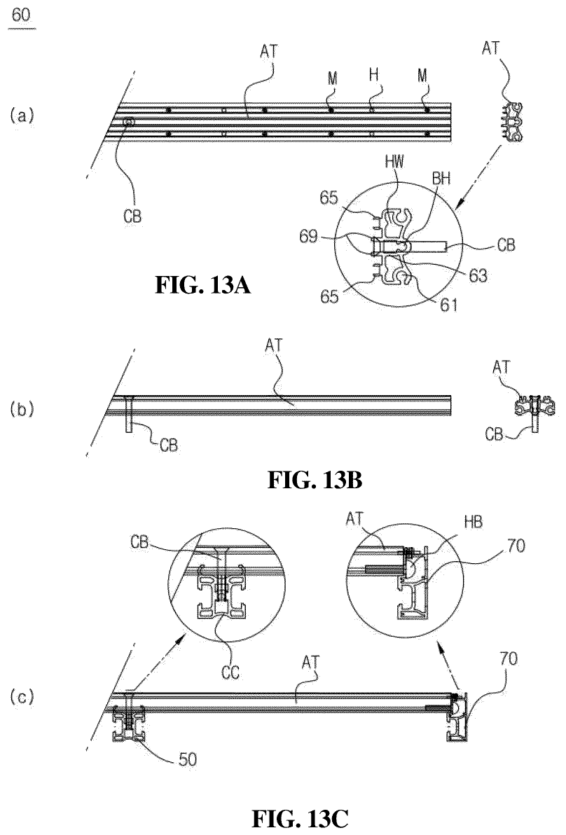

As shown in FIG. 8, the edge beam 70 has a head hole 77a and a shaft hole 77b formed spaced apart from each other with the hollow HW as the center and facing each other. As shown in FIGS. 9, 13A, 13B, and 13C, the head of a bolt, which is a vertical bolt VB or a horizontal bolt HB fastened to an end of the vertical beam 50 or the horizontal beam 60, is inserted through the head hole 77a. As shown in the drawing, the shaft hole 77b is penetrated by the shaft of the bolt provided in the head hole 77a. That is, the shaft hole 77b is penetrated by the screw shaft of the bolt having threads. Accordingly, the edge beam 70 is connected to the vertical beam 50 and the horizontal beam 60 by the fastening of the vertical bolt VB or the horizontal bolt HB, thereby forming an integral part with the vertical beam 50 and the horizontal beam 60.

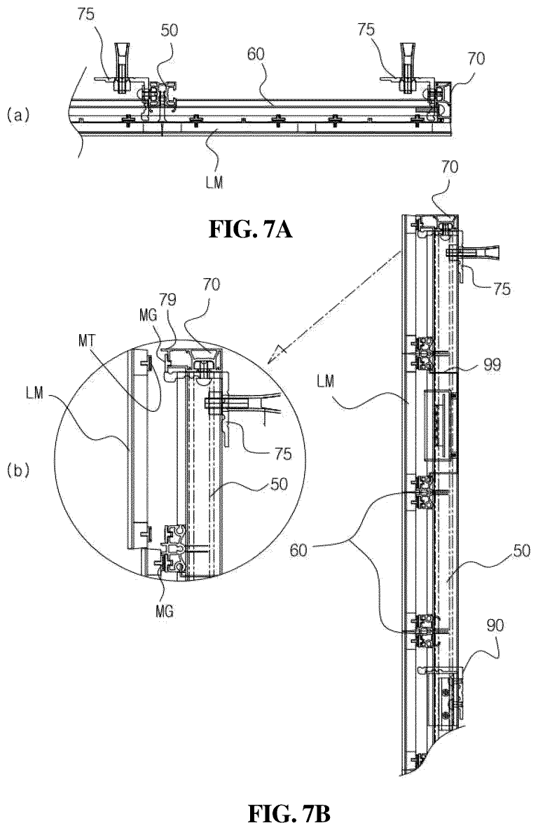

As shown in FIGS. 7A to 8, the edge beam 70 is provided with another magnetic body or magnet MG that provides an attractive force to a metallic magnetic body MT or magnet provided on the rear side of the LED module LM described later. As shown, the edge beam 70 has the magnetic body or magnet MG installed on one side thereof facing the rear side of the LED module LM. As shown in FIG. 9, the magnet MG is provided with a screw integrally and is fixed to the edge beam 70 by screw connection. The edge beam 70 is tapped at the portion where the magnet MG is screwed for screw connection of the magnet MG. At this time, the edge beam 70 is tapped after an uneven protrusion 70b described later at the portion where tapping is performed is removed. Thus, the magnet MG is easily screwed to the edge beam 70 by tapping.

As shown in FIGS. 7A to 8, the edge beam 70 provides magnetic force, by means of the magnet MG, to the metal plate-type magnetic body MT or magnet provided at the rear side of the LED module LM. Accordingly, the LED module LM is fixed at the front of the edge beam 70 by the magnetic force, as shown in the drawing.

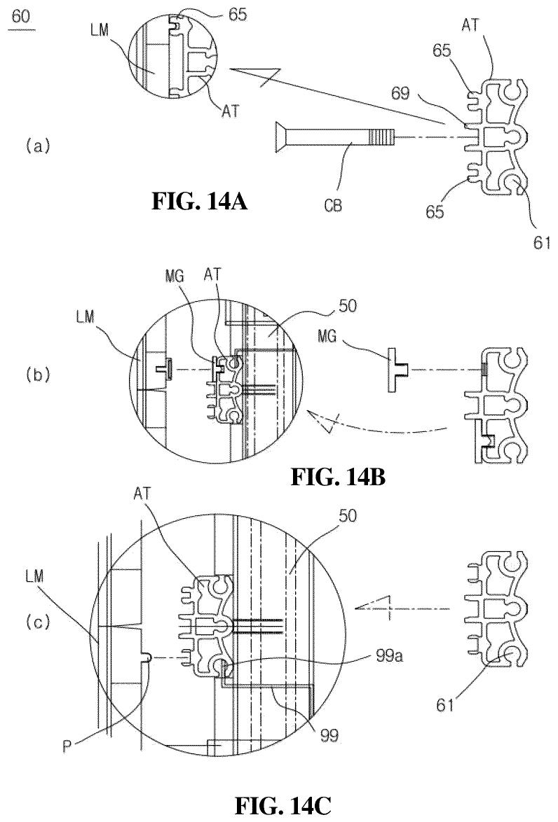

As shown in FIG. 8, the edge beam 70 may be provided with the uneven protrusion 70b on one side thereof facing the rear side of the LED module LM. As shown in FIGS. 14A to 14C, a catch pin P provided on the rear side of the LED module LM is inserted into and caught in a groove-shaped recessed portion of the uneven protrusion 70b. In other words, the uneven protrusion 70b is a holder that provides a groove into which the catch pin P is inserted and caught. Thus, the LED module LM is centered in the correct position as the catch pin P is inserted into the recessed portion, and is restrained by the edge beam 70 as the catch pin P is fitted into the recessed portion and caught in the recessed portion, thereby preventing downward displacement. In particular, when the LED module LM is lowered by the weight thereof, the catch pin P is caught more firmly in the recessed portion, preventing the LED module LM from falling.

Unlike the case shown in FIG. 8, the edge beam 70 may be configured so that the screw of the magnet MG described above is coupled to the recessed portion of the uneven protrusion 70b. At this time, the uneven protrusion 70b is machined with a female screw tapped into the recessed portion. Depending on the structure of the LED module LM, the uneven protrusion 70b is machined with a female screw or a female screw is threaded using a tap after the uneven protrusion 70b is removed.

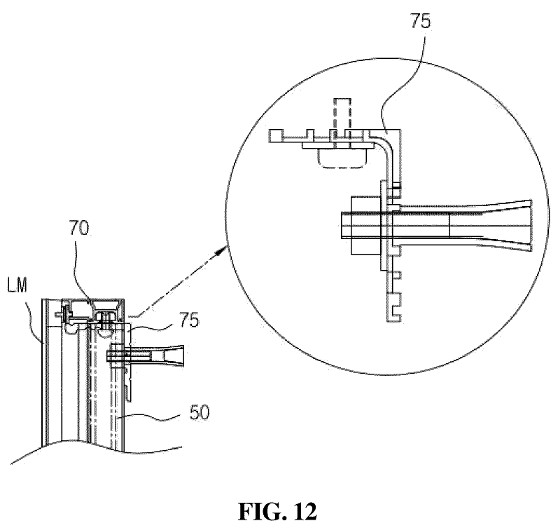

As shown in FIG. 8, the edge beam 70 is formed with a support protrusion 79 protruding on one side thereof facing the rear side of the LED module LM. The support protrusion 79 supports the rear side of the LED module LM as shown in FIGS. 7A, 7B, and 12. Accordingly, the LED modules LM are easily installed as the rear sides thereof are supported by the edge beams 70, and the LED modules protrude at the front of the edge beams 70 with the same protrusion length to maintain the same flatness.

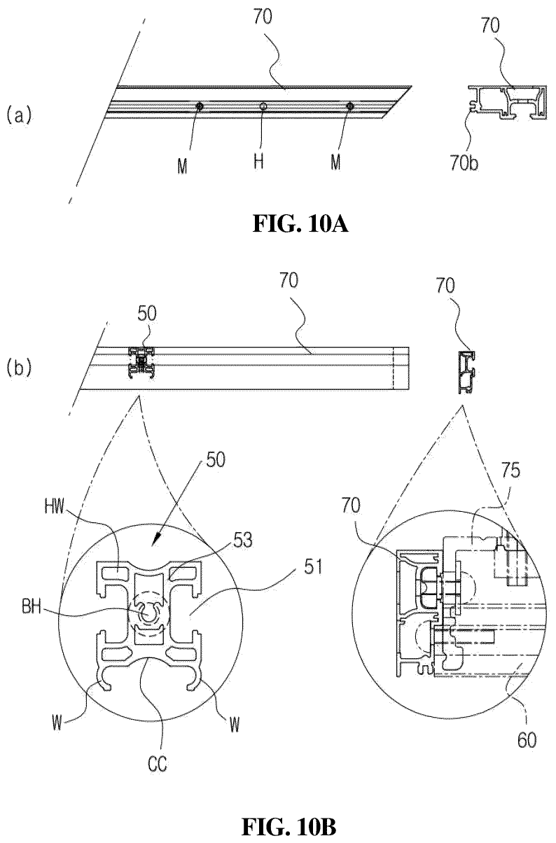

As shown in FIG. 8, the edge beam 70 is provided with a groove-shaped catch holder 71 that has a cross section of approximately “Ω” so as to be open on one side. As shown in FIGS. 7A, 7B, 10A, and 10B, a head of a bolt or a nut fastened to a bolt for fixing an anchor bracket 75 described later is slidably inserted into the catch holder 71. Accordingly, the anchor bracket 75 is integrally fixed to the edge beam 70 by the bolt and nut that are inserted and caught in the catch holder 71.

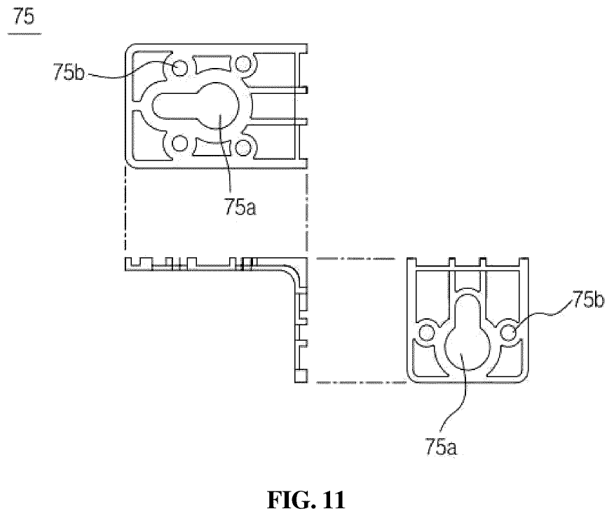

As shown in FIGS. 7A to 9, the anchor bracket 75 is integrally fixed to the edge beam 70 and/or the vertical beam 50 by means of the bolt and nut. The anchor bracket 75 is composed of a bent plate bent at a right angle as shown in FIGS. 11 and 12 and has a horizontal surface and a vertical surface. As shown, one of the horizontal or vertical surfaces of the anchor bracket 75 is integrally fixed to the edge beam 70 or the vertical beam 50 using the bolt and nut.

As shown in FIGS. 7A to 9, the anchor bracket 75 is fixed to the edge beam 70 or the vertical beam 50 by the aforementioned bolt penetrating the horizontal surface and then being fastened to the aforementioned nut. As shown, the anchor bracket 75 is fixed to a wall or column (not shown) by a conventional anchor bolt penetrating the vertical surface of the anchor bracket 75 and being fastened to the wall or column. Accordingly, the anchor bracket 75 fixes the edge beam 70 or the vertical beam 50 to the wall or column.

As shown in FIGS. 11 and 12, the anchor bracket 75 is formed such that one of the horizontal or vertical surfaces is longer. For example, the anchor bracket is formed such that the horizontal surface is longer than the vertical surface, as shown. Depending on the distance from the wall or column, either the horizontal or vertical surface of the anchor bracket 75 is fixed to the edge beam 70 or the vertical beam 50. For example, when the edge beam 70 or the vertical beam 50 is close to the wall or column, the vertical surface which is shorter is fixed to the edge beam 70 or the vertical beam 50, and when the edge beam 70 or the vertical beam 50 is far away, the horizontal surface which is longer is fixed to the edge beam 70 or the vertical beam 50. As shown in FIG. 12, when the vertical surface of the anchor bracket 75 is fixed to the edge beam 70 or the vertical beam 50, the anchor bracket 75 protrudes slightly outward from the edge beam 70 or the vertical beam 50, whereas when the horizontal surface of the anchor bracket 75 is fixed to the edge beam 70 or the vertical beam 50, the anchor bracket 75 protrudes more from the edge beam 70 or the vertical beam 50. Accordingly, the protrusion length of the anchor bracket 75 is varied according to the distance from the wall or column. Thus, the worker can easily fix the edge beam 70 or the vertical beam 50 to the wall or the column. In particular, since the protrusion length of the anchor bracket 75 is varied according to the distance from the wall or the column, the edge beam 70 or the vertical beam 50 is firmly fixed to and supported by the wall or the column.

As shown in FIGS. 11 and 12, the anchor bracket 75 has an elongated through-hole 75a through which the screw shaft of the bolt or anchor bolt described above passes. As shown, the elongated through-hole 75a is configured asymmetrically with one side larger. The screw shaft of the bolt or anchor bolt is inserted through the larger one side of the elongated through-hole 75a and then inserted into the smaller other side. Accordingly, the bolt or anchor bolt is fixed to the anchor bracket 75 stably as the outer surface of the screw shaft of the bolt or anchor bolt is supported after the screw shaft is easily inserted into one side and then into the other side of the elongated through-hole 75a.

As shown in FIGS. 11 and 12, the anchor bracket 75 is formed with a plurality of screw holes 75b centered on the elongated through-hole 75a. The screw holes 75b are penetrated by screws (not shown) that are fastened to the edge beam 70 or the vertical beam 50. Thus, the anchor bracket 75 is more firmly fixed to the edge beam 70 or the vertical beam 50 by the screws of the screw holes 75b.

In this case, it is preferable that the aforementioned vertical beam 50 be composed of the same aluminum profile as the edge beam 70, as shown in FIGS. 10A and 10B. That is, the vertical beam 50 may be composed of a hollow tube in which a rib 53 and a hollow HW are formed, as shown. The vertical beam 50 is provided with a side holder 51 in the form of a groove with a cross section of approximately “Ω” on at least one of the two sides, as shown. As shown in FIG. 8, a bolt or nut for fixing another member to the side is inserted into the vertical beam 50. For example, as shown, a nut to which a bolt of the aforementioned anchor bracket 75 is fastened is inserted into the vertical beam 50. Accordingly, the anchor bracket 75 is integrally fixed to the side of the vertical beam 50.

As shown in FIGS. 10A and 10B, the vertical beam 50 is provided with a bolt hole BH in the center thereof. As shown in FIG. 9, the vertical bolt VB that penetrates the head hole 77a and the shaft hole 77b of the edge beam 70 is fastened to the bolt hole BH of the vertical beam 50. Accordingly, the vertical beam 50 is vertically fixed to the edge beam 70 as shown.

As shown in FIGS. 7A, 7B, and 8, the vertical beam 50 is integrally connected with the horizontal beam 60 by a fixing bolt CB penetrating the horizontal beam 60 horizontally arranged at the front of the vertical beam 50. As shown in FIGS. 6, 13A, 13B, and 13C, the fixing bolt CB is fastened to the intersection where the vertical beam 50 intersects the horizontal beam 60 in a grid. At this time, the fixing bolt CB is fastened to the vertical beam 50 and the horizontal beam 60 in a penetrating state as the screw threads to which the fixing bolt CB is fastened are tapped in the vertical beam 50 and the horizontal beam. Accordingly, the vertical beams 50 form a grid together with the horizontal beams 60 as shown in FIGS. 5 and 6.

As shown in FIG. 8, the vertical beam 50 has a concave part CC formed at the front thereof, that is, the portion where the fixing bolt CB is fastened. Due to the characteristics of the concave structure, the concave part CC guides the fixing bolt CB to the center of the vertical beam 50. Thus, the fixing bolt CB is easily fastened to the center of the vertical beam 50 by the concave part CC. It is preferable that the concave part CC is also formed at the rear of the vertical beam 50 as illustrated for the purpose of screw fastening, material saving, and weight reduction.

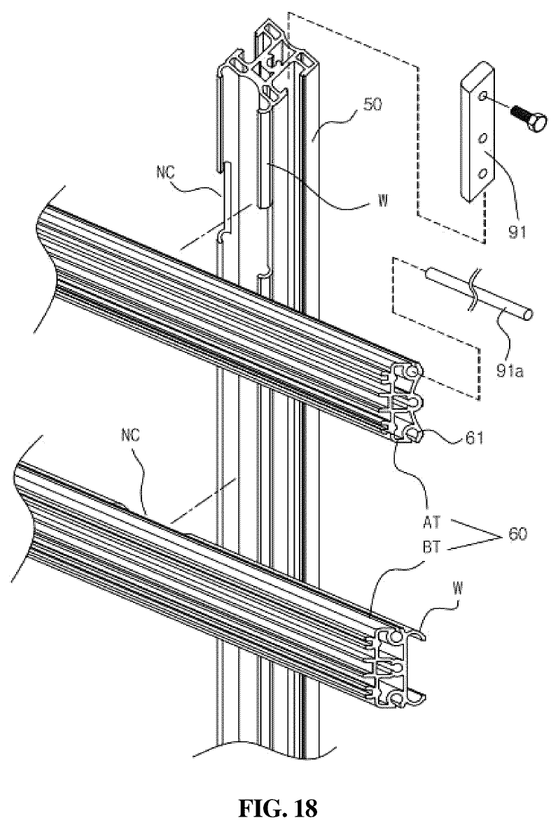

As shown in FIGS. 10A, 10B, and 18, the vertical beam 50 is provided with a protruding wing W on each side of the front where the horizontal beam 60 is fixed. As shown in the drawing, the protruding wings W of the vertical beam 50 are formed along the length direction. As shown, the vertical beam 50 has a notch NC cut to a size corresponding to the thickness of the horizontal beam 60 formed at the portion where the horizontal beam 60 is joined. As shown, the horizontal beam 60 is inserted into the notch NC of the vertical beam 50 in a horizontal manner. Accordingly, the horizontal lower surface of the horizontal beam 60 is supported by the notch NC of the vertical beam 50, and the horizontal upper and lower surfaces of the horizontal beam 60 are respectively hung on the upper and lower sides of the notch NC. Thus, the horizontal beam 60 is stably fixed to the vertical beam 50 by the support of the notch NC, and does not come off upward or downward of the vertical beam 50 by hanging on the notch NC.

Unlike the case shown in the drawing, the vertical beam 50 may optionally be provided with another magnetic body or magnet MG that provides an attractive force to the metallic magnetic body MT or magnet provided on the rear side of the LED module LM to be described later, so that the LED module LM to be described later may be installed.

As shown in FIGS. 7A, 7B, 13A, 13B, and 13C, it is preferable that the horizontal beam 60 be manufactured by the same extrusion as the edge beam 70 or the vertical beam 50 and be composed of an aluminum profile having a rib 63 and a hollow HW. As shown, the horizontal beam 60 has a bolt hole BH formed on the inside thereof, and the horizontal bolt HB that horizontally penetrates the edge beam 70 is fastened to the bolt hole BH. Accordingly, the horizontal beam 60 is fixed to the edge beam 70 at an end thereof in a horizontal state.

As shown in FIGS. 13A to 14C, the horizontal beam 60 is provided with a holder, that is, an uneven protrusion 65 into which the catch pin P formed on the rear side of the LED module LM is inserted and caught, in a protruding state on the front thereof facing the LED module LM. Accordingly, the LED module LM is centered in the correct position as the catch pin P is inserted into the recessed portion of the uneven protrusion 65, and is restrained by the horizontal beam 60 as the catch pin P is caught in the recessed portion, thereby preventing downward displacement.

As shown in FIGS. 13A to 14C, the horizontal beam 60 is provided with a support protrusion 69 on the front thereof where the uneven protrusion 65 provided. As shown, the support protrusion 69 is configured as a pair, and the pair of support protrusions 69 protrude in a spaced-apart state in the center of the front of the horizontal beam 60. As shown, the support protrusions 69 face the rear side of the LED module LM. As shown, the support protrusions 69 support the rear side of the LED module LM that is magnetically attached to the horizontal beam 60. At this time, the support protrusions 69 respectively support the upper LED module LM and the lower LED module LM with the center of the front side as the center, as shown. Accordingly, the protrusion lengths of the LED modules LM protruding forward from the horizontal beam 60 become the same as the rear sides thereof are supported by the support protrusions 69.

As shown in the enlarged view of 14A, the horizontal beam 60 may support the rear side of the LED module LM with the uneven protrusion 65. In this case, in order to reduce material costs, the support protrusions 69 of the horizontal beam 60 may be omitted as shown in the enlarged view.

The horizontal beam 60 is fixed orthogonally at the front of the vertical beam 50 as described above and shown in FIGS. 13A to 14C. As shown, the horizontal beam 60 maintains a grid state together with the vertical beam 50 as the fixing bolt CB penetrates horizontally and is connected to the vertical beam 50 at the rear of the horizontal beam 60. As shown in FIGS. 13A to 14C, the horizontal beam 60 has the fixing bolt CB passing through between the support protrusions 69. Thus, the fixing bolt CB may pass through the center of the front side of the horizontal beam 60.

As shown in FIGS. 14A to 14C, on one of the upper and lower portions of the horizontal beam 60, a groove-shaped protrusion holder 61 formed with a cross section of approximately “(” and having one open side is provided. As shown, a fitting protrusion 99a of a board housing 99 described later is inserted into and fixed to the protrusion holder 61 of the horizontal beam 60.

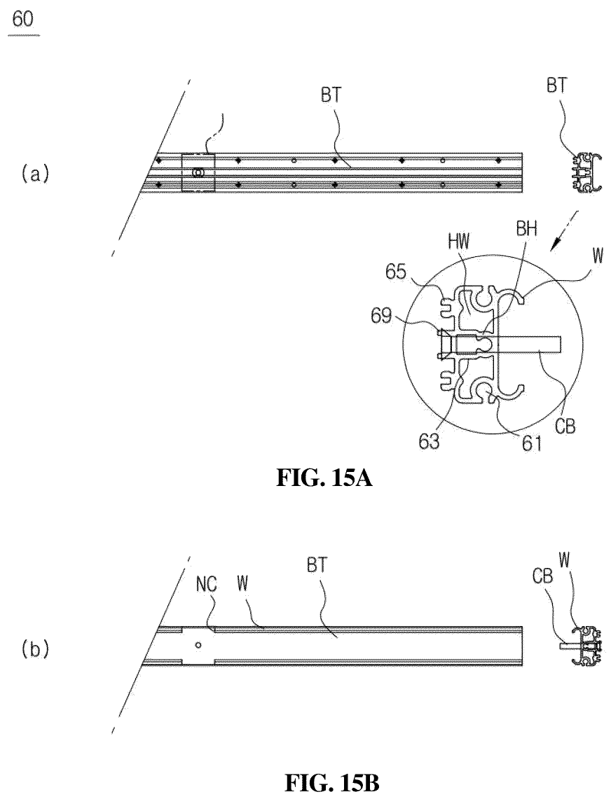

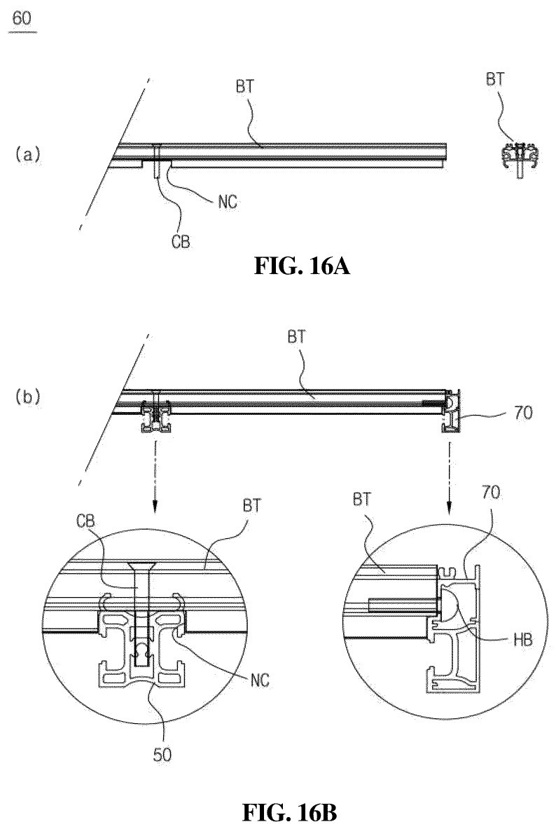

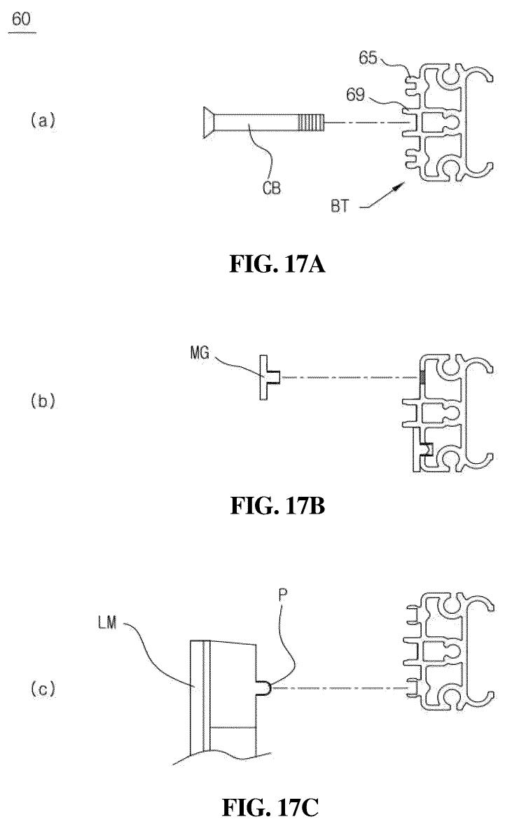

As shown in FIGS. 15A to 16B, the horizontal beam 60 may be provided with protruding wings W on the rear side facing the vertical beam 50. As shown in FIGS. 16A, 16B, and 18, the horizontal beam 60 has the protruding wings W formed along the length direction. As shown, the horizontal beam 60 has a notch NC cut to a size corresponding to the thickness of the vertical beam 50 formed at the portion where the vertical beam 50 is joined. As shown, the vertical beam 50 is inserted into the notch NC of the horizontal beam 60 in a vertical manner. Accordingly, the vertical beam 50 is restrained by having both sides caught in the notch NC of the horizontal beam 60. Thus, the horizontal movement of the vertical beam 50 is suppressed by being caught in the notch NC of the horizontal beam 60.

The horizontal beam 60 may have the notch NC thereof being combined with the notch NC of the vertical beam 50 as shown in FIG. 18. In this case, the horizontal beam 60 and the vertical beam 50 are suppressed from both horizontal and vertical movements by the respectively combined notches NC.

Unlike the case shown in the drawing, the vertical beam 50 may be coupled to the notch NC of the horizontal beam 60 with the notch NC formed at the portion where the horizontal beam 60 having the notch NC is joined.

In this case, the horizontal beam 60 is composed of an A type AT without the protruding wings W as shown in FIGS. 13A to 14C and a B type BT with the protruding wings W as shown in FIGS. 15A to 16B. It is preferable that the horizontal beam 60 be a combination of A type AT and B type BT as shown in FIG. 9. Accordingly, the horizontal beam 60 is able to support both sides of the vertical beam 50 by means of the notch NC formed in the protruding wings W of the B type BT to prevent the vertical beam 50 from moving.

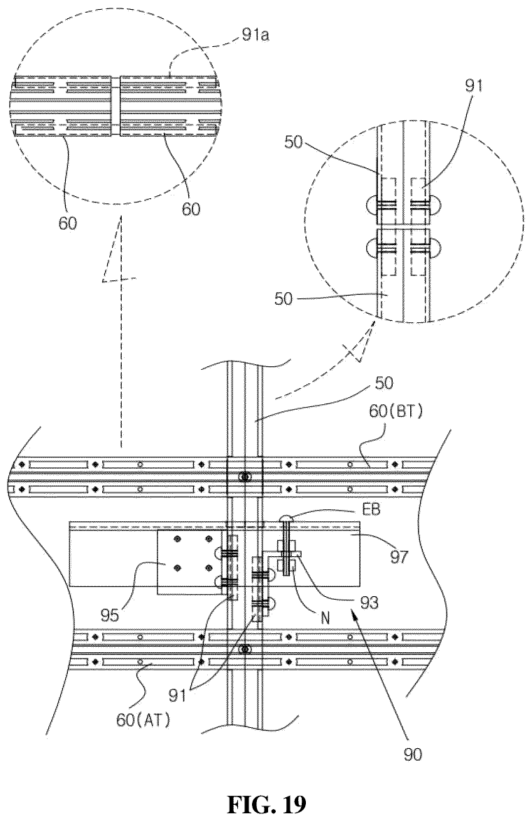

As shown in FIGS. 6 and 19, the vertical beam 50 may be raised or lowered by a horizontal adjuster 90 installed between the horizontal beams 60. As shown, the horizontal adjuster 90 adjusts the height of the vertical beam 50 installed on the inside of the edge beam 70 to adjust the horizontality of the horizontal beam 60.

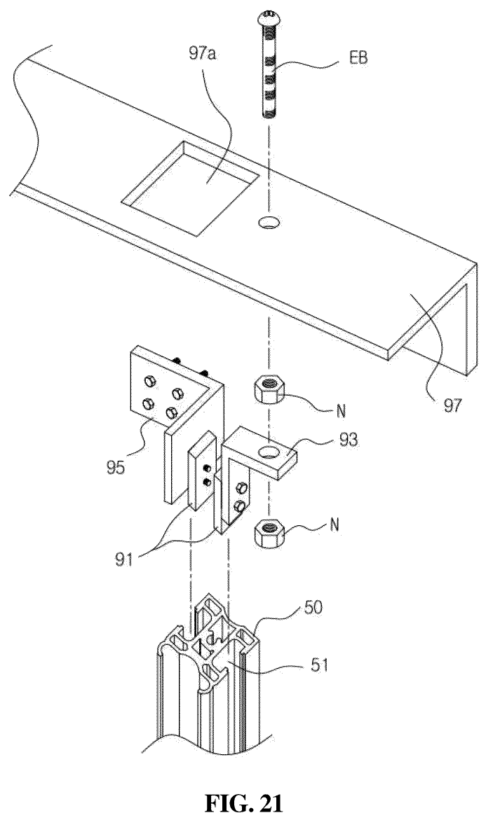

As shown in FIGS. 19 to 21, the horizontal adjuster 90 may, for example, consist of a lifting plate 93, a nut N, a crossbar 97, and a lifting bolt EB. The lifting plate 93 is integrally fixed to the vertical beam 50 and is raised and lowered together with the vertical beam 50. As shown, the lifting plate 93 is formed in a right-angled shape, and the lower portion of the lifting plate 93 is bolted to an insert plate 91 inserted into the side holder 51 of the vertical beam 50 from the outside of the vertical beam 50. As shown, the lifting plate 93 is formed to a size wider than the insert plate 91 and is fixed to the insert plate 91 with the lower portion thereof hanging on the outer surface of the vertical beam 50. At this time, the lower portion of the lifting plate 93 and the insert plate 91 substantially hold the vertical beam 50. Thus, when the lifting plate 93 is raised or lowered, the lifting plate 93 pulls the insert plate 91 to raise or lower the vertical beam 50.

As shown in FIGS. 19 to 21, the nut N is provided on each of the bent upper and lower portions of the lifting plate 93. As shown in the drawing, the lifting bolt EB is vertically fastened to the nuts N.

As shown in FIGS. 19 to 21, the crossbar 97 is composed of an angle bar having a length and is installed horizontally on the vertical beam 50 as shown. The crossbar 97 is installed horizontally between the horizontal beams 60 as shown. The crossbar 97 is integrally connected to the vertical beam 50 by means of the lifting plate 93 and the lifting bolt EB as shown. As shown, a fixing plate 95 is bolted to an insert plate 91 inserted into a side holder 51 on the other side of the vertical beam 50, and the fixing plate 95 is fixed to the crossbar 97 by bolting as shown. Accordingly, the crossbar 97 is fixed more firmly to the vertical beam 50 by means of the fixing plate 95. Thus, the crossbar 97 distributes the load transmitted to the vertical beam 50.

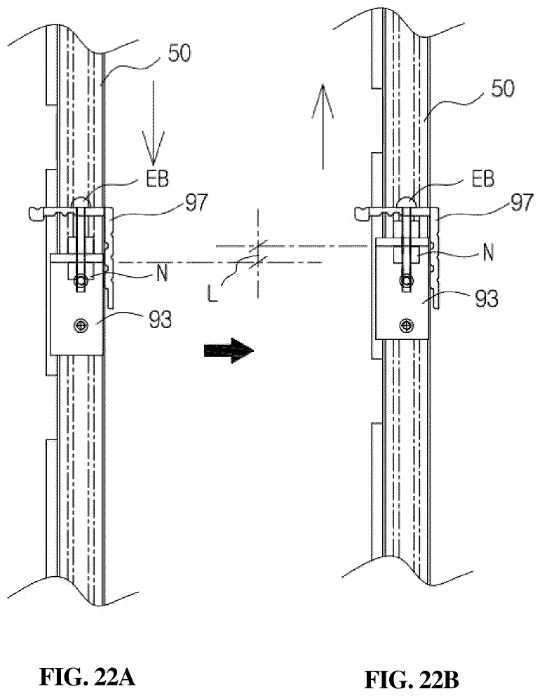

As shown in FIGS. 19 to 21, the lifting bolt EB vertically penetrates the crossbar 97 and is pivotally connected to the nut N of the lifting plate 93. The lifting bolt EB raises and lowers the nut N as shown in FIGS. 22A-22B through pivot rotation. At this time, the nut N raises and lowers the vertical beam 50 together with the lifting plate 93 as shown.

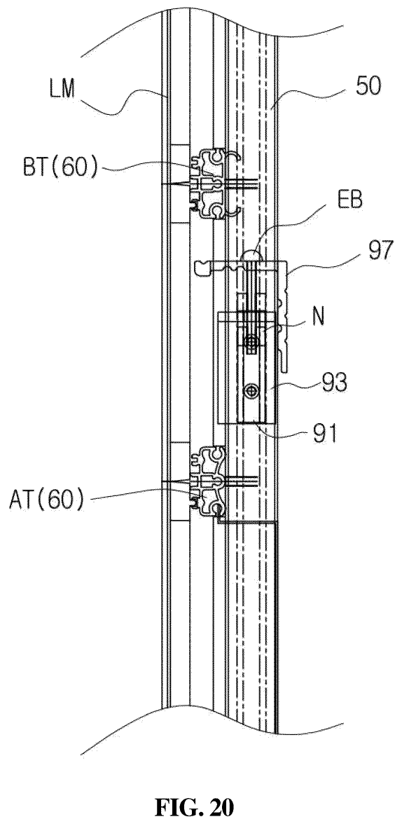

In contrast, the nut N may be raised and lowered along the screw shaft of the lifting bolt EB by the worker to raise and lower the lifting plate 93. At this time, as shown in FIGS. 19 and 20, the nut N may raise the lifting plate 93 as the upper nut is first forcibly lifted by the worker and then the lower nut is forcibly lifted. Accordingly, the lifting plate 93 raises the vertical beam 50 by being connected to the vertical beam 50 by means of the fixing plate 95.

The lifting bolt EB or the nut N raises the vertical beam 50 only about 2 mm to 5 mm. Accordingly, the vertical beam 50 raises and lowers the horizontal beam 60 installed horizontally along the length direction to adjust the horizontality of the horizontal beams 60. Thus, even if the LED modules LM installed on the horizontal beam 60 have a horizontal defect or accumulated error, the horizontal defect or accumulated error may be easily corrected as the horizontality of the horizontal beams 60 is adjusted.

Meanwhile, when the plurality of vertical beams 50 is configured and connected vertically, the plurality of vertical beams 50 is connected using the insert plate 91 described above as shown in FIG. 18. As shown in an enlarged view in FIG. 19, as the two ends of the insert plate 91 are respectively inserted into the side holders 51 of the vertical beams 50 that are vertically aligned and then bolted, the vertical beams 50 vertically aligned are connected as one piece. Accordingly, the vertical beams 50 aligned vertically may firmly maintain a vertical state.

In addition, when the plurality of horizontal beams 60 is configured and connected horizontally, the plurality of horizontal beams 60 is connected integrally using a connection rod 91a as shown in FIG. 18. As shown in enlarged views in FIGS. 18 and 19, opposite ends of the connection rod 91a are inserted into the protrusion holders 61 of the horizontal beams 60 connected in a horizontal row to connect the horizontal beams 60 as one piece. Thus, the horizontal beams 60 connected in a horizontal row may easily maintain a horizontal state.

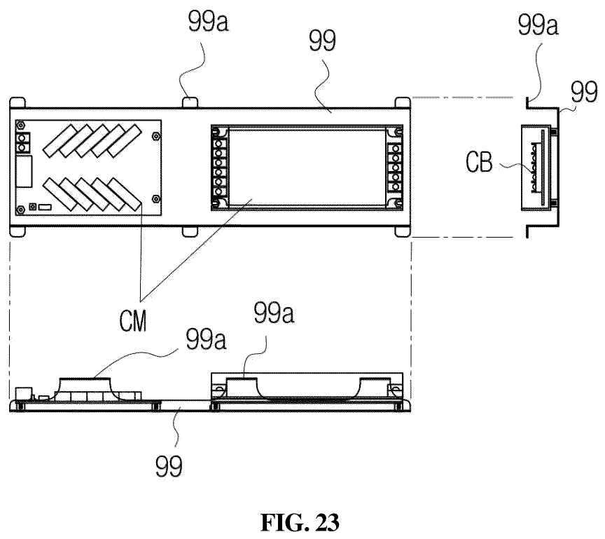

Meanwhile, as shown in FIG. 23, the aforementioned board housing 99 is configured as a channel-shaped plate. As shown, the board housing 99 has a control module CB mounted on the inside thereof to control power or drive. As shown, the board housing 99 has the fitting protrusion 99a formed in an orthogonal state at each open end thereof. As shown in FIGS. 14A to 14C, the fitting protrusion 99a is inserted into and caught on the groove-shaped protrusion holder 61 integrally formed on the upper or lower portion of the horizontal beam 60 with one side open. Accordingly, the board housing 99 is detachably fixed to the horizontal beam 60.

Meanwhile, as shown in FIGS. 8 and 9, the edge beam 70 has a step surface 70a. As shown, the edge beam 70 is provided with the step surface 70a on a side facing the end side of the horizontal beam 60 or the vertical beam 50. As shown, the edge beam 70 supports a portion of the end side of the horizontal beam 60 or the vertical beam 50 in a hanging state on the step surface 70a.

As shown in FIGS. 8 and 9, the vertical beam 50 or the horizontal beam 60 has a cut surface 50a or 60a and a protruding surface 60a or 60b corresponding to the step surface 70a of the edge beam 70. As shown, since the cut surface 50a or 60a and the protruding surface 60a or 60b are aligned with the step surface 70a of the edge beam 70, a portion of the vertical beam 50 or the horizontal beam 60 is supported. Accordingly, the vertical beam 50 or the horizontal beam 60 is firmly fixed to the edge beam 70.

In an embodiment of the present disclosure configured as described above, a square frame is manufactured by means of the edge beam 70 as shown in FIGS. 5 and 6. As shown, the edge beam 70 is manufactured as a square frame by inserting the bent plate 70f into the corner, that is, the end having an inclined surface, and then bolting the bent plate 70f. As shown in FIG. 9, the edge beam 70 provides the uneven protrusion 70b and the support protrusion 79 on the front side thereof to which the LED module LM is attached. As shown, in the edge beam 70, after a portion of the uneven protrusion 70b removed, the magnet MG is fixed by screw connection. Accordingly, the edge beam 70 provides a magnetic force to the LED module LM by means of the magnet MG to fix the LED module LM, prevents the LED module LM from being detached as the catch pin P of the LED module LM is caught by the uneven protrusion 70b, and supports the rear side of the LED module LM by means of the support protrusion 79.

As shown in FIGS. 5 and 6, the vertical beam 50 is installed vertically on the edge beam 70 forming a square frame. As shown in FIG. 9, the vertical beam 50 is integrally fixed to the edge beam 70 by the vertical bolt VB passing through the head hole 77a and shaft hole 77b of the edge beam 70 and being fastened to the bolt hole BH. Thus, the edge beams 70 provide a square installation frame having the vertical beams 50 on the inside of the square frame thereof.

As shown in FIGS. 6 and 18, the horizontal beam 60 is installed by being fitted horizontally into the notch NC of the protruding wings W of the vertical beam 50. As shown, the horizontal beam 60 is integrally fixed to the vertical beam 50 as the fixing bolt CB penetrates the horizontal beam 60 and is fastened to the concave part CC formed in the center of the front side of the vertical beam 50. At this time, since the fixing bolt CB is guided to the center of the vertical beam 50 through the concave part CC, the fixing bolt CB is easily fastened to the center of the vertical beam 50. Thus, the vertical beams 50 form a grid together with the horizontal beams 60. Since the vertical beam 50 and the horizontal beam 60 that constitute the inner beam are installed on the inside of the square frame of the edge beams 70, the edge beams 70 provide a square grid-shaped installation frame.

As shown in FIGS. 13A to 13C, the horizontal beam 60 is integrally fixed at one end to the edge beam 70 as the horizontal bolt HB penetrates the head hole 77a and the shaft hole 77b of the edge beam 70 and is fastened to the bolt hole BH. As shown in FIGS. 14A to 14C, the horizontal beam 60 provides the uneven protrusion 65 and the pair of support protrusions 69 on the front side thereof to which the LED module LM is attached. As shown, after a portion of the uneven protrusion 65 of the horizontal beam 60 is removed, the magnet MG is fixed by screw connection. As shown, the horizontal beam 60 is fastened to the vertical beam 50 as the fixing bolt CB passes through the pair of support protrusions 69. The fixing bolt CB may easily pass through the center of the horizontal beam 60 because the fixing bolt CB passes through the support protrusions 69.

As shown in FIGS. 13A to 16B, not only the horizontal beam 60 of the A type AT without the protruding wings W but also the horizontal beam 60 of the B type BT with the protruding wings W is installed on the vertical beam 50. As shown in FIG. 18, the horizontal beam 60 has the notch NC formed in the protruding wings W of the B type BT, and when the horizontal beam 60 is installed horizontally, the vertical beam 50 is fitted into the notch NC of the horizontal beam 60. Thus, due to the notch NC, the horizontal beam 60 may suppress the vertical beam 50 from moving horizontally due to vibration or the like.

As shown in FIGS. 14A to 14C, the fitting protrusion 99a of the board housing 99 is fitted into the protrusion holder 61 formed on the upper and lower portions of the horizontal beam 60. Accordingly, the board housing 99 is detachably fixed to the horizontal beam 60 together with the control module CM.

Meanwhile, as shown in FIGS. 7A to 8, in the vertical beam 50, the anchor bracket 75 is fixed by means of the bolt and nut fastened to the side holder 51. The anchor bracket 75 is also installed to the edge beam 70 through a bolt and nut fastened to the catch holder 71 of the edge beam 70 as shown. The anchor bracket 75 secures the edge beam 70 and the vertical beam 50 to the wall or column (not shown) by the anchor bolt that penetrates the anchor bracket 75 and is fastened to the wall or column. The anchor bracket 75 is firmly fixed to the edge beam 70 or the vertical beam as the screws of the screw holes 75b are fastened to the edge beam 70 or the vertical beam 50, and the anchor bolt is easily inserted as the anchor bolt is inserted through one side of the asymmetrically formed elongated through-hole 75a and then moved to the other side thereof. Depending on the distance from the wall or column, one of the horizontal or vertical surface of the anchor bracket 75 is fixed to the edge beam 70 or the vertical beam 50 and the other is fixed to the wall or column by the anchor bolt. Since the protrusion length of the anchor bracket 75 for the wall or column varies depending on the distance from the wall or column, the installation frame composed of the edge beams 70 and the vertical beams 50 is easily fixed to the wall or column.

As shown in FIGS. 8 and 9, the horizontal beam 60 fixed to the wall or column together with the vertical beam 50, and the LED module LM is installed at the front of the horizontal beam 60 along the length direction. As shown, the horizontal beam 60 provides magnetic force using the magnet MG at the front to fix the LED module LM at the front. The catch pin P of the LED module LM is inserted into and caught in the groove of the uneven protrusion 65 provided at the front of the horizontal beam 60. As shown, the horizontal beam 60 supports the rear side of the LED module LM with the support protrusions 69 at the front. Thus, the LED module LM is easily fixed to the horizontal beam 60 by magnetic force, is stably fixed by the catch pin P to prevent falling, and is supported by the support protrusions 69 so as to not protrude excessively forward and remain horizontal.

As shown in FIGS. 16A, 16B, and 18, when the horizontal beam 60 is provided with the protruding wings W, a portion of the protruding wings W is cut to provide the notch NC. As shown, the horizontal beam 60 is connected to the vertical beam 50 by means of the fixing bolt CB with the vertical beam 50 inserted into the notch NC, thereby suppressing the horizontal movement of the vertical beam 50 using the notch NC. Accordingly, the vertical beam 50 may stably maintain a vertical state even when vibrations, etc., occur.

The horizontal beam 60 is corrected for horizontal irregularity or accumulated horizontal error by the horizontal adjuster 90 shown in FIGS. 19 to 22B. As shown, the horizontal adjuster 90 raises and lowers the nut N by pivoting the lifting bolt EB of the crossbar 97, and raises and lowers the lifting plate 93 together with the vertical beam 50 by means of the nut N. Thus, the horizontal beam 60 is corrected for horizontal defects or accumulated errors by the raising and lowering of the vertical beam 50.

As shown in FIGS. 14A, 14B, 14C, and 23, the fitting protrusion 99a of the board housing 99 is fitted into the protrusion holder 61 formed on the upper and lower portions of the horizontal beam 60. Accordingly, the board housing 99 is detachably fixed to the horizontal beam 60 with the control module CM mounted thereon.

As shown in FIG. 8, the horizontal beam 60 has the cut surface 60a and the protruding surface 60b thereof aligned with the side of the edge beam 70 provided with the step surface 70a. At this time, as shown, the protruding surface 60b of the horizontal beam 60 is caught in the step created by the step surface 70a of the edge beam 70. Accordingly, the horizontal beam 60 is firmly fixed to the side of the edge beam 70 to prevent movement.

As shown in FIG. 9, the cut surface 50a and the protruding surface 50b of the vertical beam 50 are aligned with and hung on one side of the edge beam 70 provided with the step surface 70a. Accordingly, the vertical beam 50 is firmly fixed to the lower side of the edge beam 70 to prevent movement.

In this case, the LED module LM described above may be installed at the front of the vertical beam 50 if another magnetic body or magnet MG that provides an attractive force to the metallic magnetic body MT or magnet provided on the rear side of the LED module LM is provided on the vertical beam 50. Since this technology can be easily understood by those skilled in the art by referring to the magnetic body or magnet ME provided in the horizontal beam 60 or the edge beam 70, a detailed description thereof is omitted.

In the above embodiment of the present disclosure, since the LED module LM is directly attached to the components of the installation frame consisting of a vertical beam and an edge beam, a horizontal beam and an edge beam, or a vertical beam, a horizontal beam, and an edge beam, the conventional cabinet may be omitted, and accordingly, post-processing caused by the cabinet, occurrence of a variety of errors and accumulated errors resulting therefrom may be minimized.

In particular, since the cabinet is omitted, the overall dead weight is greatly reduced, which reduces the stress on the wall. Accordingly, the restriction criteria for the wall on which the present disclosure is to be installed may be expanded. Furthermore, since the edge beam 70, the vertical beam 50, and the horizontal beam 60 are hollow aluminum profile beams, weight reduction is possible and processing such as cutting or slicing may be easily performed.

In addition, since the edge beam 70 is provided with the head hole 77a and the shaft hole 77b, a bolt may be inserted through the edge beam 70 and fixed in a hidden state on the inside of the edge beam 70. Since the magnet MG is mounted on the edge beam 70 by screw connection, the edge beam 70 may provide magnetic force to the LED module LM, and since the catch pin P of the LED module LM is inserted into the uneven protrusion 70b of the edge beam 70 and caught, the LED module LM may be centered in the correct position and stably fixed.

In addition, since the support protrusion 79 is provided on the edge beam 70, the rear of the LED module LM may be supported to limit the protrusion distance of the LED module LM, and since a bolt head or nut is inserted into the catch holder 71, other parts may be detachably fixed through the bolt or nut.

In addition, since the bolt hole BH is provided in the vertical beam 50, the vertical beam 50 may be easily fixed to the edge beam 70 by bolting, and since a bolt head or nut is inserted into the side of the vertical beam 50, other parts may be detachably fixed through the bolt or nut.

Furthermore, since along the length direction of the vertical beam 50, the notch NC is formed into which the horizontal beam 60 is inserted and caught, the vertical movement of the horizontal beam 60 may be suppressed while the horizontal beam 60 is supported by means of the notch NC. Since the protruding wings W are provided which are partially cut to form the notch NC, the notch NC may be easily formed, and since the concave part CC is provided at the intersection where the vertical beam 50 intersects the horizontal beam 60, the fixing bolt CB penetrating the horizontal beam 60 may be guided to the center of the vertical beam 50 by the concave part CC.

In addition, since the bolt hole BH is provided in the horizontal beam 60, the horizontal beam 60 may be easily fixed to the edge beam 70 by bolting, and since the protrusion holder 61 into which the fitting protrusion 99a of the board housing 99 is fitted is provided on the upper or lower portion of the horizontal beam 60, the board housing 99 may be removably fixed. Since the magnet MG is mounted on the horizontal beam 60 by screw connection, a magnetic force may be provided to the LED module LM.

Furthermore, since the catch pin P of the LED module LM is inserted into the uneven protrusion 65 of the horizontal beam 60 and caught, the LED module LM may be centered in the correct position and stably fixed, and since the pair of support protrusions 69 are provided in a spaced-apart state on the horizontal beam 60, the rear of the LED modules LM may be supported individually by the support protrusions 69, thereby limiting the protrusion distance of the LED modules LM. Since the fixing bolt CB is inserted between the support protrusions 69, the fixing bolt CB may be easily fastened to the center of the horizontal beam 60.

Furthermore, since the LED module LM is provided with the catch pin P so that the catch pin P is caught on the uneven protrusion 65 and 70b, vertical movement or falling of the LED module LM may be prevented, and horizontal irregularity or accumulated error of the horizontal beam 60 may be corrected by means of the horizontal adjuster 90. Since the vertical beam 50 may be raised and lowered by means of the lifting plate 93 having the pivoting lifting bolt EB and the nut N fastened to the lifting bolt EB, the horizontality of the horizontal beams 60 may be easily corrected through the raising and lowering of the vertical beam 50.

The above-described embodiments merely describe preferred embodiments of the present disclosure, and thus the scope of application of the present disclosure is not limited thereto, and appropriate modifications (changes in structure or configuration, partial omissions, or supplements) are possible within the scope of the same idea, as long as the essential features can be satisfied. In addition, the above-described embodiments may have some or many of the features combined with each other. Accordingly, the structure and configuration of each component shown in the embodiments of the present disclosure may be implemented by modification or combination, and it is natural that such modification or combination of the structure and configuration falls within the scope of the appended claims of the present disclosure.

What is claimed is:

1. An LED display board comprising:
a square installation frame consisting of a plurality of edge beams connected in a square ring shape to provide a square frame, and an inner beam consisting of at least one of a plurality of vertical beams or a plurality of horizontal beams installed spaced apart on an inside of the edge beams; and
a plurality of LED modules detachably installed at a front of at least one of the plurality of horizontal beams, the plurality of vertical beams, and the plurality of edge beams of the installation frame, and each having a magnetic body or magnet on a rear side thereof so as to be detachably fixed to the at least one of the plurality of horizontal beams, the plurality of vertical beams, and the plurality of edge beams using a magnetic force,
wherein the plurality of horizontal beams, the plurality of vertical beams, and the plurality of edge beams of the installation frame to which the plurality of LED modules is fixed is provided with another magnetic body or magnet that provides an attractive force to the magnetic body or the magnet of each of the LED modules.

2. The board of claim 1, wherein each of the edge beams of the installation frame is provided with a head hole, into which a head of a bolt that is fastened to an end of each of the vertical beams or horizontal beams is inserted, and a shaft hole, through which a shaft of the bolt having threads formed passes, separated from each other, and is composed of a tube with a hollow formed therein, wherein the head hole and the shaft hole face each other with the hollow as a center.

3. The board of claim 1, wherein at least one of each of the vertical beams or each of the horizontal beams of the installation frame further comprises a notch into which a portion of a counterpart to be joined in the grid is inserted and hung,
wherein the each of the vertical beams and horizontal beams is prevented from being detached by having the portion thereof supported on an inside of the notch or caught in the notch as the portion thereof is inserted into the notch.

4. The board of claim 1, wherein each of the horizontal beams of the installation frame has a bolt hole formed at an end thereof to which a bolt is fastened that horizontally penetrates each of the edge beams, is composed of a tube with a hollow formed therein, and further comprises an uneven protrusion on which the another magnetic body or magnet is installed.

5. The board of claim 1, further comprising:
a catch pin protruding on the rear side of the each of the LED modules provided with the magnetic body or magnet; and
a groove-shaped holder formed integrally with each of the horizontal beams, vertical beams, and edge beams of the installation frame and into which the catch pin is inserted and caught.
